(19) United States
(12) Patent Application Publication
(10) Pub. No.: US 2025/0279293 A1
(43) Pub. Date: Sep. 4, 2025

(54) SUBSTRATE PROCESSING APPARATUS AND SUBSTRATE PROCESSING METHOD

(71) Applicant: SCREEN Holdings Co., Ltd., Kyoto (JP)

(72) Inventors: Kyosuke MURATA, Kyoto (JP); Shuzo NAGAMI, Kyoto (JP); Tomohiro TAKAHASHI, Kyoto (JP)

(21) Appl. No.: 19/067,676

(22) Filed: Feb. 28, 2025

(30) Foreign Application Priority Data
Mar. 1, 2024 (JP) 2024-031344

(51) Int. Cl. H01L 21/67; G05B 19/418; H01L 21/311

(52) U.S. Cl. CPC H01L 21/67086; G05B 19/4188; H01L 21/31111; G05B 2219/31001; G05B 2219/45031

(57) ABSTRACT

A substrate processing apparatus includes a processing tank including a wall defining an internal space to store a processing liquid, a lifter to hold a substrate and immerse the substrate in the processing liquid, a plurality of processing liquid nozzles to discharge the processing liquid into the internal space of the processing tank from a plurality of respective different positions in the processing tank, a heating device including a plurality of heaters to respectively heat a plurality of different regions of the wall, and a controller to individually control discharge of the processing liquid from the plurality of processing liquid nozzles and individually control outputs of the plurality of heaters. The controller may individually control the outputs of the plurality of heaters according to a discharge state of the processing liquid from the plurality of processing liquid nozzles.

### CROSS REFERENCE TO RELATED APPLICATIONS

This application claims priority based on Japanese Patent Application No. 2024-031344 filed on Mar. 1, 2024, the entire contents of which are incorporated herein by reference.

### BACKGROUND OF THE INVENTION

### 1. Field of the Invention

The present invention relates to a substrate processing apparatus and a substrate processing method for processing a substrate with a processing liquid. Examples of substrates which are processing targets include a semiconductor wafer, a substrate for flat panel displays (FPD) such as a liquid crystal display and an organic electroluminescence (EL) display, a substrate for an optical disk, a substrate for a magnetic disk, a substrate for a magneto-optical disk, a substrate for a photomask, a ceramic substrate, and a substrate for a solar cell.

### 2. Description of the Related Art

In the related art, substrate processing apparatuses that perform processing by immersing a plurality of substrates in a processing liquid stored in a processing tank are used, and an example thereof is disclosed in Japanese Patent Application Publication No. 2014-103297. The substrate processing apparatus disclosed in Japanese Patent Application Publication No. 2014-103297 includes a processing tank in which an overflow tank is defined at an outer circumferential portion of an upper end of a storage tank having an open upper end portion, a processing liquid circulation portion, and substrate transport means. The processing liquid is stored in the storage tank, and the plurality of substrates are immersed in the processing liquid. A processing liquid inlet/outlet is defined in a bottom portion of the storage tank, and a processing liquid outlet is defined in the bottom portion of the overflow tank. The processing liquid is suctioned from the processing liquid outlet of the overflow tank by the processing liquid circulation portion, and the processing liquid is supplied to the processing liquid inlet/outlet of the storage tank, whereby the processing liquid is circulated. The substrate transport means is configured by horizontally attaching four substrate holding bodies to a lower end portion of an arm that can be lifted and lowered, and holds the plurality of substrates in a vertical state in parallel at predetermined intervals in a front-rear direction. A transport arm can lower the substrate holding bodies to immerse the plurality of substrates in the processing liquid stored in the storage tank, and the transport arm can lift the substrate holding bodies to take out the plurality of substrates from the processing liquid. A rubber heater is bonded to a wall of the storage tank. The rubber heater heats the wall of the storage tank, thereby heating the processing liquid inside the storage tank to a predetermined temperature.

### SUMMARY OF THE INVENTION

However, in the prior art of Japanese Patent Application Publication No. 2014-103297, uniformity of processing (for example, uniformity of an etching amount) in a principal surface of a substrate is not always sufficient, and there is room for improvement.

In this respect, according to a preferred embodiment of the present invention, there are provided a substrate processing apparatus and a substrate processing method enabling uniformity of processing in a principal surface of a substrate to be improved.

According to a preferred embodiment of the present invention, there are provided a substrate processing apparatus and a substrate processing method having the following exemplified feature.
1. A substrate processing apparatus including:
   a processing tank including a wall defining an internal space to store a processing liquid,
   a lifter that has a holding portion which holds a substrate and that is to immerse the substrate held by the holding portion in the processing liquid stored in the internal space,
   a plurality of processing liquid nozzles to discharge the processing liquid into the internal space from a plurality of respective different positions in the processing tank,
   a heating device including a plurality of heaters to respectively heat a plurality of different regions of the wall, and
   a controller that is configured or programmed to individually control discharge of the processing liquid from the plurality of processing liquid nozzles and individually control outputs of the plurality of heaters.

According to this configuration, the discharge of the processing liquid from the plurality of different positions is individually controlled, and the heating of the plurality of different regions of the wall of the processing tank is individually controlled. Consequently, the processing liquid in the processing tank can be evenly applied to each portion of a principal surface of the substrate, and accordingly, the evenness of the processing in the principal surface of the substrate can be improved.
2. The substrate processing apparatus according to clause 1, wherein the controller is configured or programmed to individually control the outputs of the plurality of heaters depending on a discharge state of the processing liquid from the plurality of processing liquid nozzles.

According to this configuration, the heating state of the plurality of different regions of the wall of the processing tank is controlled depending on the discharge state of the processing liquid from the plurality of different positions. Consequently, since an appropriate heating state can be realized depending on the discharge state of the processing liquid, the processing liquid in the processing tank can be evenly applied to each portion of the principal surface of the substrate, and accordingly, the evenness of the processing in the principal surface of the substrate can be improved.
3. The substrate processing apparatus according to clause 1. or 2, wherein the controller is configured or programmed to individually control the outputs of the plurality of heaters so as to heat a processing liquid in a discharge region of a processing liquid nozzle (specifically a region in the vicinity of a discharge port of the processing liquid nozzle) through which discharge of the processing liquid is stopped, among the plurality of processing liquid nozzles.

According to this configuration, since the processing liquid in the discharge region of the processing liquid nozzle through which the discharge is stopped can be heated, a temperature of the processing liquid can be adjusted by a heater in a region where the locally temperature adjustment is difficult to perform by supplying the processing liquid. Consequently, since temperature unevenness of the processing liquid in the processing tank can be prevented, the evenness of the processing in the principal surface of the substrate can be improved.
4. The substrate processing apparatus according to any one of clauses 1. to 3, wherein the controller is configured or programmed to individually control discharge/stop of the processing liquid through the plurality of processing liquid nozzles, and individually control the outputs of the plurality of heaters so that a heat generation amount of a heater closest to the processing liquid nozzle through which the processing liquid is discharged is small (for example, energization OFF) and a heat generation amount of a heater closest to the processing liquid nozzle through which no processing liquid is discharged is large (for example, energization ON).

According to this configuration, heating by the heater near the processing liquid nozzle through which the processing liquid is discharged is weakened, and heating by a heater near the processing liquid nozzle through which no processing liquid is discharged is intensified. Consequently, local heating by the heaters can be appropriately controlled depending on a degree of temperature adjustment by the supply of the processing liquid, and as a result, temperature unevenness in the processing tank can be prevented. This enables the evenness of the processing in the principal surface of the substrate to be improved.
5. The substrate processing apparatus according to any one of clauses 1. to 4, wherein the wall includes a first side wall and a second side wall facing each other, and a bottom wall,
   the plurality of heaters include a first side wall heater to heat the first side wall, a second side wall heater to heat the second side wall, and a bottom wall heater to heat the bottom wall,
   the plurality of processing liquid nozzles include a first side wall nozzle to discharge a processing liquid from the first side wall toward an inside of the internal space, a second side wall nozzle to discharge a processing liquid from the second side wall toward the inside of the internal space, and a bottom wall nozzle to discharge a processing liquid from the bottom wall toward the inside of the internal space, and
   the controller is configured or programmed to execute at least one of
   first side wall discharge control to discharge a processing liquid from the first side wall nozzle and to stop an output of the first side wall heater,
   second side wall discharge control to discharge a processing liquid from the second side wall nozzle and to stop an output of the second side wall heater, and
   bottom wall discharge control to discharge a processing liquid from the bottom wall nozzle and to stop an output of the bottom wall heater.

In the first side wall discharge control, since, in the vicinity of the first side wall nozzle, the temperature adjustment is performed by the processing liquid discharged from the first side wall nozzle, the output of the first side wall heater is stopped. Also, in the second side wall discharge control, since, in the vicinity of the second side wall nozzle, the temperature adjustment is performed by the processing liquid discharged from the second side wall nozzle, the output of the second side wall heater is stopped. Similarly, in the bottom wall discharge control, since the temperature adjustment is performed by the processing liquid discharged from the bottom wall nozzle in the vicinity of the bottom wall nozzle, the output of the bottom wall heater is thus stopped. In this manner, the outputs of the heaters can be appropriately controlled depending on the discharge of the processing liquid, whereby the evenness of the processing in the principal surface of the substrate can be improved.
6. The substrate processing apparatus according to clause 5, wherein the controller is configured or programmed to stop discharge of a processing liquid from the second side wall nozzle and to cause the second side wall heater to enter a heat generation state when simultaneously executing the first side wall discharge control and the bottom wall discharge control.

According to this configuration, the region in the vicinity of the second side wall nozzle through which no processing liquid is discharged is heated by the second side wall heater. Consequently, since temperature unevenness of the processing liquid in the processing tank can be prevented, the evenness of the processing in the principal surface of the substrate can be improved.
7. The substrate processing apparatus according to clause 5. or 6, wherein the controller is configured or programmed to stop discharge of processing liquids from the first side wall nozzle and the second side wall nozzle and to cause the first side wall heater and the second side wall heater to enter a heat generation state when performing the bottom wall discharge control.

According to this configuration, the regions in the vicinity of the first side wall nozzle and the second side wall nozzle through which no processing liquid is discharged are heated by the first side wall heater and the second side wall heater, respectively. Consequently, since temperature unevenness of the processing liquid in the processing tank can be prevented, the evenness of the processing in the principal surface of the substrate can be improved.
8. The substrate processing apparatus according to any one of clauses 1. to 7, wherein the wall includes a pair of end walls facing each other in an arrangement direction that is a predetermined horizontal direction, a pair of side walls which face each other in an intersecting direction that is a horizontal direction intersecting (typically orthogonal to) the arrangement direction and are coupled to the pair of end walls, and a bottom wall coupled to the pair of end walls and the pair of side walls,
   the holding portion is to hold a plurality of substrates arranged in the arrangement direction in a standing posture,
   the lifter includes a back portion connected to the holding portion, and is to immerse the plurality of substrates in the processing liquid in the processing tank in a state in which the back portion is interposed between the plurality of substrates and a first end wall which is one of the pair of end walls,
   the plurality of heaters include an end wall heater disposed on the first end wall and a plurality of zone heaters disposed on at least one of the pair of side walls and the bottom wall in a plurality of respective regions divided in the arrangement direction, and the heating device does not include a heater disposed on a second end wall that is the other of the pair of end walls, and
   the controller is configured or programmed to individually control outputs of the plurality of zone heaters.

According to this configuration, the processing tank has the pair of end walls, the pair of side walls, and the bottom wall, and the processing liquid is stored in the internal space defined by the walls. The immersion of the plurality of substrates held by the lifter in the processing liquid stored in the processing tank enables the plurality of substrates to be collectively processed with the processing liquid. In a state in which the plurality of substrates are immersed in the processing liquid, the back portion of the lifter is interposed between the plurality of substrates and the first end wall. More specifically, the back portion of the lifter is interposed between the first end wall and a substrate closest to the first end wall among the plurality of substrates.

In the processing tank, the heaters that heat the processing liquid stored in the processing tank by heating the walls constituting the processing tank are provided. Specifically, the end wall heater is provided on the first end wall which is one of the end walls facing each other in the arrangement direction, and the end wall heater heats the first end wall. Also, the plurality of zone heaters are disposed in the plurality of regions divided in the arrangement direction, and each zone heater heats the wall on which the corresponding zone heater is disposed, that is, at least one of the pair of side walls and the bottom wall. The end wall heater is disposed on the first end wall, while no heater is disposed on the second end wall. Hence, the second end wall is not directly heated by the heater. Therefore, the processing liquid stored in the processing tank may have a temperature distribution having a gradient in the arrangement direction.

In this respect, the zone heaters heat at least one of the pair of side walls and the bottom wall in the plurality of respective regions divided in the arrangement direction, and the zone heaters are individually controlled by the controller. Consequently, since the heating of the plurality of regions divided in the arrangement direction can be individually controlled, the processing liquid in the processing tank can be appropriately heated in each of the region close to the first end wall and the region close to the second end wall. Specifically, an even temperature distribution having a small gradient in the arrangement direction can be made. This enables the evenness of the processing performed on the plurality of substrates to be improved.

It is noted that, the standing: posture is typically a vertical posture in which the principal surface of the substrate is parallel to the vertical direction. Also, a holding portion of the lifter typically is to hold the plurality of substrates in parallel such that the principal surfaces of the adjacent substrates face each other. Typically, a normal direction of the principal surface of the substrate is parallel to the arrangement direction.

Also, the controller may further configured or programmed to individually control the end wall heater. Also, the end wall heater is typically disposed on an outer surface of the first end wall. Similarly, the zone heaters are typically disposed on an outer surface of at least one of the pair of side walls and the bottom wall. No heater is disposed on an outer surface of the second end wall.

At least two regions and preferably three or more regions divided in the arrangement direction are provided. By locating the zone heaters in the three or more divided regions, respectively, and individually controlling the zone heaters, the temperature distribution of the processing liquid in the arrangement direction can become more even. That is, in a region in the vicinity of the first end wall which is heated by the end wall heater and is positioned with the lifter interposed between the substrate and the first end wall, a region in the vicinity of the second end wall that is not heated by the heater, and an intermediate region between the regions, the walls constituting the processing tank can be appropriately and individually heated.
9. The substrate processing apparatus according to clause 8, wherein the plurality of zone heaters include a first zone heater disposed in a region closest to the first end wall among the plurality of regions and a second zone heater disposed in a region closest to the second end wall among the plurality of regions, and
   the controller is configured or programmed to control the outputs of the plurality of zone heaters so that the second zone heater has a heat generation amount (more specifically, a heating generation amount per unit length in the arrangement direction) larger than that of the first zone heater.

According to this configuration, a larger amount of heat can be supplied to the processing liquid in the processing tank in the region close to the second end wall on which no end wall heater is disposed than in a region close to the first end wall on which the end wall heater is disposed. Consequently, the temperature distribution of the processing liquid in the arrangement direction can become even.
10. The substrate processing apparatus according to clause 8. or 9, further including an outer tank having a storage space to receive a processing liquid overflowing from the processing tank, wherein the storage space has an end portion space having a depth equal to or larger than a depth of the internal space of the processing tank in a region facing an outer surface of the second end wall.

According to this configuration, the overflowing of the processing liquid from the processing tank to the outer tank enables the processing to be performed on the plurality of substrates while the processing liquid is supplied to the processing tank, the processing liquid is circulated in the processing tank, and switching between the substrates is performed. The storage space of the outer tank has the end portion space having the depth substantially equal to or deeper than the depth of the internal space of the processing tank in the region facing the outer surface of the second end wall. This end portion space may, for example, overlap the entire second end wall when viewed in the arrangement direction. Such a deep end portion space is advantageous in that a circulation flow rate can be increased, for example, in a case where the processing liquid is pumped out from the outer tank and circulated to the processing tank through a circulation path.

A pump is typically installed on the circulation path. If an entrance end of the circulation path is disposed at a deep position in the storage space of the outer tank, that is, in the vicinity of a bottom portion of the end portion space, it is possible to prevent the entrance end of the circulation path from being exposed to the air and entering a liquid shortage state even when the circulation flow rate is increased using a high-capacity pump.
11. The substrate processing apparatus according to any one of clauses 8. to 10, further including a lid to open and close an opening of the processing tank, in which
   the heating device further includes a lid heater disposed on the lid.

The opening of the processing tank is typically defined by the pair of end walls and upper edges of the pair of side walls, and the plurality of substrates are taken into and out of the internal space of the processing tank through the opening by the lifter. According to the above configuration, since the lid is heated by the lid heater disposed on the lid of the processing tank, the processing liquid can also be heated from above. Consequently, the processing liquid can be prevented from being cooled, and the temperature distribution of the processing liquid can become still more even.
12. The substrate processing apparatus according to any one of clauses 8. to 11, wherein, at least one of the plurality of zone heaters has a plurality of heater portions divided in an up-down direction, and the controller is configured or programmed to individually control the plurality of heater portions.

According to this configuration, the heat generation amounts of the plurality of heater portions divided in the up-down direction of the zone heater can be individually controlled. Consequently, the temperature distribution of the processing liquid in the up-down direction can become even. This enables the processing in the principal surface of each substrate to become even.
13. A substrate processing method including:
   immersing a substrate in a processing liquid stored in a processing tank including a wall defining an internal space to store the processing liquid,
   a discharge control to individually control discharge of a processing liquid from a plurality of different positions in the processing tank to the internal space by a controller, and
   a heating control to individually control, by the controller, a plurality of heaters so as to respectively heat a plurality of different regions of the wall.
14. This substrate processing method may be combined with one or more of the features described above with respect to the substrate processing apparatus.

The above and yet other objects, features, and effects of the present invention will become more apparent from the following description of the preferred embodiments made with reference to the attached drawings.

### BRIEF DESCRIPTION OF THE DRAWINGS

FIG. 1 is a conceptual diagram for illustrating a configuration example of a substrate processing apparatus according to a preferred embodiment of the present invention.

FIG. 2 is a perspective view for illustrating a configuration example of a lifter.

FIG. 3 is a perspective view for illustrating a configuration example of a processing tank.

FIG. 4 is a block diagram for illustrating a control system of an end wall heater, a first side wall heater, a second side wall heater, and a bottom wall heater.

FIGS. 5A to 5D are views for illustrating an example of a relationship between discharge control of a processing liquid from a processing liquid nozzle and control (heating control) of a heating device.

FIG. 6A is a flowchart for illustrating an example of processing.

FIG. 6B is a flowchart for illustrating another example of the processing.

FIG. 7 is a diagram for illustrating a second preferred embodiment of the present invention.

FIG. 8 is a diagram for illustrating a third preferred embodiment of the present invention.

FIG. 9 is a diagram for illustrating a fourth preferred embodiment of the present invention.

### DETAILED DESCRIPTION OF THE PREFERRED EMBODIMENTS

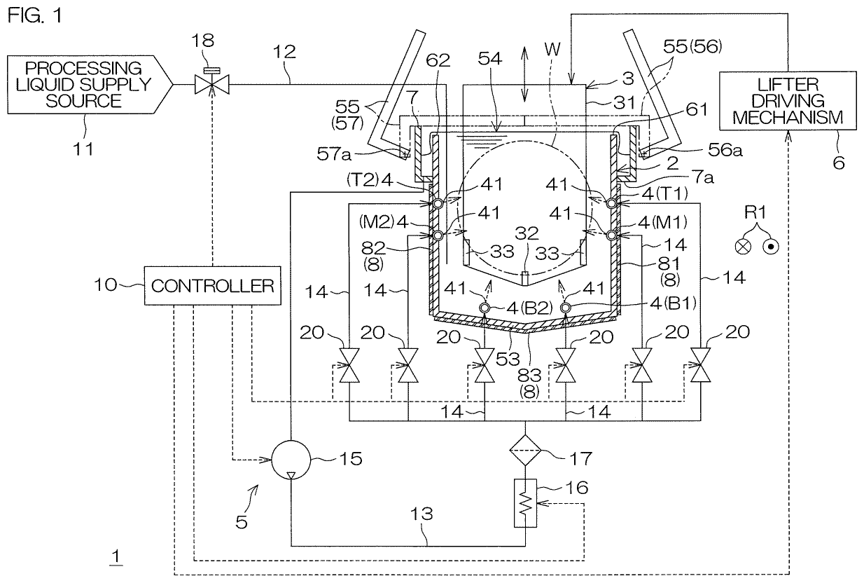

FIG. 1 is a conceptual diagram for illustrating a configuration example of a substrate processing apparatus according to a preferred embodiment of the present invention. A substrate processing apparatus 1 is a batch-type apparatus capable of collectively processing a plurality of substrates W (for example, one lot of 25 or 50 substrates) with a processing liquid. In this preferred embodiment, the substrate W is a substantially circular substrate. One typical example of the substantially circular substrate W is a semiconductor wafer.

The substrate processing apparatus 1 includes a processing tank 2 to store a processing liquid for immersing the plurality of substrates W in an internal space thereof, a lifter 3 that is to arrange and support the plurality of substrates W in a predetermined arrangement direction R1 in the processing tank 2, a plurality of processing liquid nozzles 4 to supply (more specifically, to discharge) the processing liquid into the processing tank 2, and a processing liquid supplying mechanism 5 to supply the processing liquid to the plurality of processing liquid nozzles 4. The substrate processing apparatus 1 further includes an outer tank 7 (overflow tank) to receive the processing liquid overflowing from the processing tank 2. The substrate processing apparatus 1 also includes a lifter driving mechanism 6 to move the lifter 3 up and down so as to immerse the plurality of substrates W supported by the lifter 3 in the processing liquid stored in the processing tank 2 or so as to elevate the plurality of substrates W from the processing liquid. Also, the substrate processing apparatus 1 includes a controller 10 that is configured or programmed control the processing liquid supplying mechanism 5, the lifter driving mechanism 6, and the like. The controller 10 includes a processor (CPU) and a storage device, and is configured or programmed to execute various control processes to be described below by causing a processor to execute a program stored in the storage device.

The processing liquid supplying mechanism 5 includes a new liquid supply pipe 12 through which an unused processing liquid is supplied from a processing liquid supply source 11 to the processing tank 2, and a circulation piping 13 forming a circulation path passing through the processing tank 2. An open/close valve 18 is installed in the new liquid supply pipe 12, and the open/close valve 18 is controlled to be opened and closed by the controller 10. One end of the circulation piping 13 is connected to a bottom portion of the outer tank 7, and branches into a plurality of branch piping portions 14 corresponding to the plurality of processing liquid nozzles 4, respectively, and the branch piping portions 14 are connected to the plurality of processing liquid nozzles 4, respectively.

In the circulation piping 13, a pump 15, an in-line heater 16, and a filter 17 are installed between the outer tank 7 and a branch position to the branch piping portions 14, and in this preferred embodiment, the pump 15, the in-line heater 16, and the filter 17 are disposed in this order in a direction from the outer tank 7 toward the processing liquid nozzles 4. The pump 15 and the in-line heater 16 are controlled by the controller 10. The pump 15 sends the processing liquid from the outer tank 7 toward the processing liquid nozzles 4. The in-line heater 16 is an example of a temperature adjuster to adjust a temperature of the processing liquid passing through the circulation piping 13 to an appropriate temperature. The filter 17 removes foreign matter in the processing liquid passing through the circulation piping 13.

A flow rate adjusting unit 20 is installed in each of the plurality of branch piping portions 14 connected to the plurality of processing liquid nozzles 4, respectively. Each flow rate adjusting unit 20 includes at least an open/close valve, and further includes a flow meter, a flow rate adjusting valve, or the like, as necessary. The controller 10 controls ON/OFF of the open/close valves of the flow rate adjusting units 20, thereby to control discharge/stop of the processing liquid from the processing liquid nozzles 4. Also, the controller 10 may control an opening degree of the flow rate adjusting valve provided in the flow rate adjusting unit 20 depending on a flow rate measured by the flow meter provided in the flow rate adjusting unit 20, thereby to control a flow rate of the processing liquid supplied to the processing liquid nozzle 4.

The processing liquid stored in the processing tank 2 is a chemical liquid or a rinse liquid, and is typically a chemical liquid such as an etching solution. Examples of the chemical liquid can include dilute hydrofluoric acid (DHF), hydrofluoric acid (HF) hydrofluoric nitric acid (a mixed solution of hydrofluoric acid and nitric acid (HNO₃)), buffered hydrofluoric acid (BHF), ammonium fluoride, HFEG (a mixed solution of hydrofluoric acid and ethylene glycol), phosphoric acid (H₃PO₄), sulfuric acid, acetic acid, nitric acid, hydrochloric acid, ammonia water, hydrogen peroxide water, organic acids (for example, citric acid and oxalic acid), organic alkalis (for example, TMAH: tetramethylammonium hydroxide), sulfuric acid hydrogen peroxide water mixed solution (SPM), a mixture liquid of ammonia and hydrogen peroxide water (SC1), a mixture liquid of hydrochloric acid and hydrogen peroxide water (SC2), isopropyl alcohol (IPA), a surfactant, a corrosion inhibitor, and a hydrophobic agent. The substrate processing using the chemical liquid may be etching processing or cleaning processing. As an example, a process of etching a nitride film (silicon nitride film) defined on a principal surface of the substrate W with phosphoric acid may be executed by the substrate processing apparatus 1.

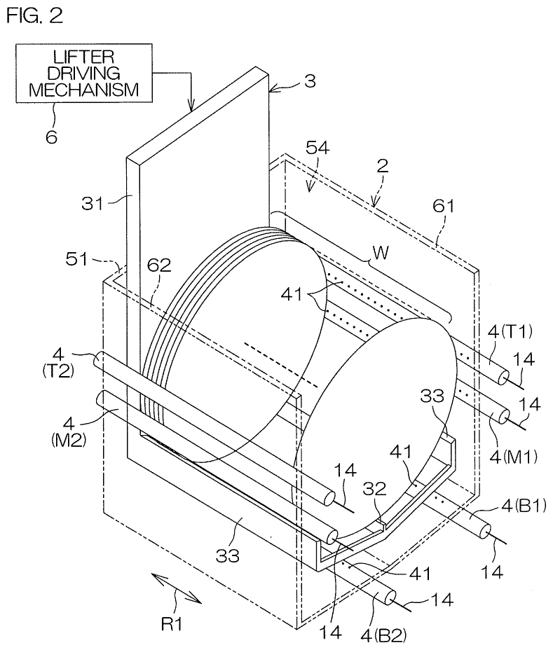

FIG. 2 is a perspective view for illustrating a configuration example of the lifter 3. The lifter 3 is lifted and lowered by the lifter driving mechanism 6 between a processing position illustrated in FIGS. 1 and 2 and a standby position above the processing tank 2. The processing position is a position where the plurality of substrates W supported by the lifter 3 are positioned in the internal space of the processing tank 2, thus being immersed in the processing liquid stored in the processing tank 2. The standby position is a position where the plurality of substrates W supported by the lifter 3 are positioned outside the processing tank 2, thus being elevated from the processing liquid stored in the processing tank 2.

In this preferred embodiment, the lifter 3 includes a back plate 31 (back portion), a center holding portion 32, and a pair of side holding portions 33. The back plate 31 is a plate-shaped member extending in a depth direction of the processing tank 2, and in this preferred embodiment, extends vertically along an inner surface of one wall (end wall 51) constituting the rectangular parallelepiped processing tank 2. The center holding portion 32 and the pair of side holding portions 33 are examples of holding portions that hold the plurality of substrates W.

The center holding portion 32 and the pair of side holding portions 33 are connected to the back plate 31, and all extend in the horizontal direction from a lower portion of the back plate 31, and extend parallel to each other. The center holding portion 32 and the pair of side holding portions 33 are arranged to align and support the plurality of substrates W in the predetermined arrangement direction R1 such that the principal surfaces of the adjacent substrates W face each other with a gap between the principal surfaces. In this preferred embodiment, the arrangement direction R1 is a horizontal direction in which the center holding portion 32 and the pair of side holding portions 33 extend. In this preferred embodiment, the center holding portion 32 and the pair of side holding portions 33 are arranged to support the plurality of substrates W at equal intervals along the arrangement direction R1. When viewed in the arrangement direction R1, the pair of side holding portions 33 are disposed on both sides with the center holding portion 32 interposed between the side holding portions. The center holding portion 32 supports a central lower edge of the substrate W, and the pair of side holding portions 33 supports left and right lower edges of the substrate W. Consequently, each substrate W is supported in a standing posture (more specifically, a standing posture in which the principal surface is parallel to a vertical direction). The plurality of substrates W are supported by the lifter 3 in the standing posture in which the principal surfaces are parallel to each other. In this preferred embodiment, each principal surface of the substrate W is substantially perpendicular to the arrangement direction R1. Thus, the plurality of substrates W are supported in a parallel standing posture, and a normal direction of the principal surface of each substrate W is parallel to the arrangement direction R1.

As also illustrated in FIG. 2, in this preferred embodiment, six processing liquid nozzles 4 are provided. Specifically, the plurality of processing liquid nozzles 4 include two processing liquid nozzles, that is, a first bottom wall nozzle B1 and a second bottom wall nozzle B2, extending in the arrangement direction R1 along a bottom surface of the processing tank 2. The first bottom wall nozzle B1 and the second bottom wall nozzle B2 are disposed in parallel at intervals in the horizontal direction orthogonal to the arrangement direction R1. Also, the plurality of processing liquid nozzles 4 include two processing liquid nozzles 4, that is, a first side wall upper nozzle T1 and a first side wall lower nozzle M1, extending in the arrangement direction R1 along one side wall 61 of the processing tank 2. The first side wall upper nozzle T1 and the first side wall lower nozzle M1 are disposed in parallel at an interval in an up-down direction.

Further, the plurality of processing liquid nozzles 4 include two processing liquid nozzles 4, that is, a second side wall upper nozzle T2 and a second side wall lower nozzle M2, extending in the arrangement direction R1 along the other side wall 62 of the processing tank 2. The second side wall upper nozzle T2 and the second side wall lower nozzle M2 are disposed in parallel at an interval in the up-down direction.

Each of the processing liquid nozzles 4 is formed of a discharge pipe extending parallel to the arrangement direction R1 and has a distal end portion that is closed and a proximal end portion that is coupled to a distal end of each of the branch piping portions 14 of the circulation piping 13. In this preferred embodiment, the closed distal end portion of the processing liquid nozzle 4 is disposed on the side of the back plate 31 of the lifter 3, and the proximal end portion coupled to the branch piping portion 14 is disposed on the side opposite to the back plate 31.

The processing liquid nozzle 4 has a plurality of discharge ports 41 which are open at intervals in the arrangement direction R1. The plurality of discharge ports 41 are aligned along the arrangement direction R1. In this preferred embodiment, a main discharge direction of the processing liquid from the discharge ports 41 is a direction toward the substrates W, that is, toward an inside of the internal space of the processing tank 2. The main discharge direction of the processing liquid from the discharge ports 41 is typically a direction parallel to the principal surfaces of the substrates W, that is, a direction intersecting (more specifically, orthogonal to) the arrangement direction R1.

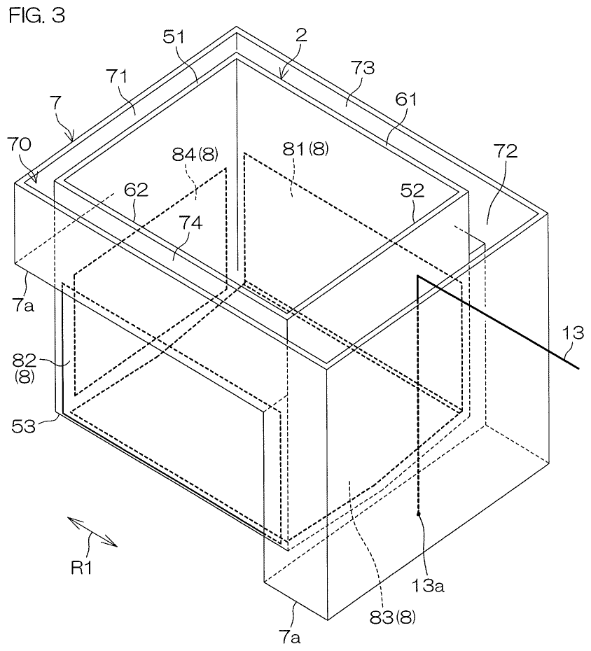

FIG. 3 is a perspective view for illustrating a configuration example of the processing tank 2 The processing tank 2 includes a pair of end walls 51 and 52 facing each other in the arrangement direction R1, a pair of side walls 61 and 62 which face each other in an intersecting direction which is a horizontal direction intersecting (in this preferred embodiment, orthogonal to) the arrangement direction R1 and are coupled to both side edges of the pair of end walls 51 and 52, respectively, and a bottom wall 53 coupled to lower edges of the pair of end walls 51 and 52 and the pair of side walls 61 and 62. Consequently, the processing tank 2 forms, for example, a rectangular parallelepiped container having an opening 54 open upward, and defines the internal space in which the processing liquid is stored. The outer tank 7 to receive the processing liquid overflowing from the processing tank 2 is provided around the processing tank 2. In this preferred embodiment, the processing tank 2 and the outer tank 7 are integrally defined and are made of, for example, quartz.

Of the pair of end walls 51 and 52, one end wall close to the back plate 31 (see FIG. 2) of the lifter 3 is referred to as a first end wall 51, and the other end wall is referred to as a second end wall 52. Also, one of the pair of side walls 61 and 62 is referred to as a first side wall 61, and the other is referred to as a second side wall 62. The opening 54 open upward is defined by upper edges of the first end wall 51, the second end wall 52, the first side wall 61, and the second side wall 62. The lifter 3 takes the plurality of substrates W in and out of the processing tank 2 through the opening 54, thereby to immerse the substrates W in the processing liquid in the processing tank 2 or to elevate the substrates W from the processing liquid.

The outer tank 7 defines a ring-shaped storage space 70 surrounding the entire perimeter of the processing tank 2 outside the processing tank 2 in a plan view. The storage space 70 includes a first end portion space 71, a second end portion space 72, a first side space 73, and a second side space 74 facing the first end wall 51, the second end wall 52, the first side wall 61, and the second side wall 62, respectively.

When viewed in the arrangement direction R1, the first end portion space 71 overlaps an upper portion of the internal space of the processing tank 2, but does not overlap a lower portion of the internal space of the processing tank 2. Similarly, when viewed in the horizontal direction orthogonal to the arrangement direction R1, the first side space 73 and the second side space 74 overlap upper portions of the internal space of the processing tank 2 but do not overlap lower portions of the internal space of the processing tank 2. That is, a bottom wall 7a of the outer tank 7 is positioned at a higher position than the bottom wall 53 of the processing tank 2 in a portion defining the first end portion space 71, the first side space 73, and the second side space 74, and the first end portion space 71, the first side space 73, and the second side space 74 are shallower than the internal space of the processing tank 2.

The second end portion space 72, on the other hand, overlaps the entire internal space of the processing tank 2 when viewed in the arrangement direction R1. That is, the bottom wall 7a of the outer tank 7 is positioned at the same height as or a lower position than the bottom wall 53 of the processing tank 2 at a portion defining the second end portion space 72, and a depth of the second end portion space 72 is substantially equal to or larger than a depth of the internal space of the processing tank 2. Consequently, the storage space 70 of the outer tank 7 has a large volume in the second end portion space 72. Accordingly, widths of the first end portion space 71, the first side space 73, and the second side space 74 can be reduced to reduce an occupied area of the outer tank 7. In this preferred embodiment, the first end portion space 71, the first side space 73 and the second side space 74 have a substantially equal width, and the second end portion space 72 has a larger width. Consequently, in such configuration, the processing liquid overflowing from the entire perimeter of the processing tank 2 is recovered, guided to the second end portion space 72 having a large volume, and stored.

An entrance end 13a of the circulation piping 13 is disposed in the vicinity of a bottom portion of the second end portion space 72, thus being disposed at a sufficiently deep position from a liquid surface of the outer tank 7. Consequently, the processing liquid can be discharged at a sufficient flow rate from the processing liquid nozzle 4 while avoiding inflow of air into the circulation piping 13, and accordingly, the processing efficiency (for example, an etching rate) by the processing liquid can be increased.

A heating device 8 is provided to heat the processing liquid stored in the processing tank 2. The heating device 8 includes an end wall heater 84, a first side wall heater 81, a second side wall heater 82, and a bottom wall heater 83.

More specifically, on an outer surface of the first end wall 51 of the processing tank 2, the end wall heater 84 is disposed at a position lower than the bottom wall 7a of the outer tank 7. The end wall heater 84 heats the first end wall 51, thereby to heat the processing liquid that is in contact with the inner surface of the first end wall 51. Since the outer tank 7 faces the entire second end wall 52, a heater that directly heats the second end wall 52 is not provided.

Also, on an outer surface of the first side wall 61, the first side wall heater 81 is disposed at a position lower than the bottom wall 7a of the outer tank 7. The first side wall heater 81 heats the first side wall 61, thereby to heat the processing liquid that is in contact with an inner surface of the first side wall 61. Similarly, on an outer surface of the second side wall 62, the second side wall heater 82 is disposed at a position lower than the bottom wall 7a of the outer tank 7. The second side wall heater 82 heats the second side wall 62, thereby to heat the processing liquid that is in contact with an inner surface of the second side wall 62. Further similarly, the bottom wall heater 83 is disposed on an outer surface (lower surface) of the bottom wall 53 of the processing tank 2. The bottom wall heater 83 heats the bottom wall 53, thereby to heat the processing liquid that is in contact with an inner surface (upper surface) of the bottom wall 53.

As illustrated in FIG. 1, a lid 55 to open and close the opening 54 of the processing tank 2 is provided. The lid 55 includes a first lid member 56 and a second lid member 57. The first lid member 56 is provided to be rotatable around a first rotation axis 56a extending horizontally on an outer side of the outer tank 7 in the vicinity of the first side wall 61. The second lid member 57 is provided to be rotatable around a second rotation axis 57a extending horizontally on an outer side of the outer tank 7 in the vicinity of the second side wall 62. The rotation axes 56a and 57a are parallel to the arrangement direction R1 in this preferred embodiment. The first lid member 56 and the second lid member 57 form an automatic cover to open and close the opening 54 by rotating around the respective rotation axes 56a and 57a in conjunction with up-down movement of the lifter 3. That is, when the lifter 3 is located at an upper position to hold the substrate W above the processing tank 2, the first lid member 56 and the second lid member 57 are located at opening positions and open the opening 54 upward. When the lifter 3 is located at a lower position to hold the substrate W in the processing tank 2, the first lid member 56 and the second lid member 57 are located at closing positions and close the opening 54 of the processing tank 2. Consequently, it is possible to suppress a temperature change of the processing liquid in the processing tank 2 and perform stable and efficient substrate processing.

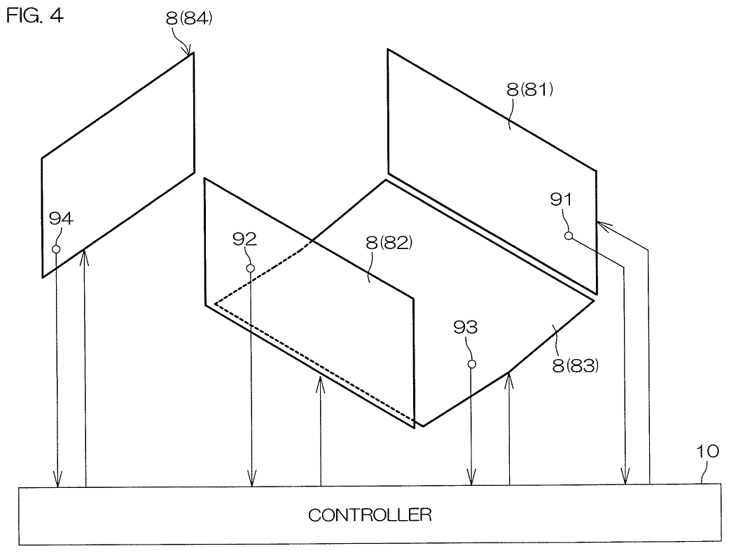

FIG. 4 is a block diagram for illustrating a control system of the end wall heater 84, the first side wall heater 81, the second side wall heater 82, and the bottom wall heater 83.

The end wall heater 84, the first side wall heater 81, the second side wall heater 82, and the bottom wall heater 83 can be typically formed of a rubber heater. The rubber heater includes, for example, a metal heater wire and a silicone cover that covers the metal heater wire. Temperature sensors 94, 91, 92, and 93 (typically thermocouples) are disposed in the end wall heater 84, the first side wall heater 81, the second side wall heater 82, and the bottom wall heater 83. The temperature sensors 94, 91, 92, and 93 detect temperatures of the end wall heater 84, the first side wall heater 81, the second side wall heater 82, and the bottom wall heater 83, respectively. Consequently, the temperature sensor 94 indirectly detects a temperature of the first end wall 51 with which the end wall heater 84 is in contact. Similarly, the temperature sensors 91, 92, and 93 indirectly detect temperatures of the side walls 61 and 62 and the bottom wall 53 with which the first side wall heater 81, the second side wall heater 82, and the bottom wall heater 83 are in contact, respectively.

Energization to the end wall heater 84, the first side wall heater 81, the second side wall heater 82, and the bottom wall heater 83 is controlled by the controller 10. The temperature sensors 94, 91, 92, and 93 are connected to the controller 10. The controller 10 controls outputs (supply power) of the end wall heater 84, the first side wall heater 81, the second side wall heater 82, and the bottom wall heater 83 based on a predetermined set temperature and detected temperatures detected by the temperature sensors 94, 91, 92, and 93.

The set temperatures for the end wall heater 84, the first side wall heater 81, the second side wall heater 82, and the bottom wall heater 83 may be equal to or different from each other. Typically, the set temperatures for the end wall heater 84, the first side wall heater 81, the second side wall heater 82, and the bottom wall heater 83 are preferably determined to have an even temperature distribution of the processing liquid in the processing tank 2 (to have a minimum variation) based on experiments or simulations performed in advance.

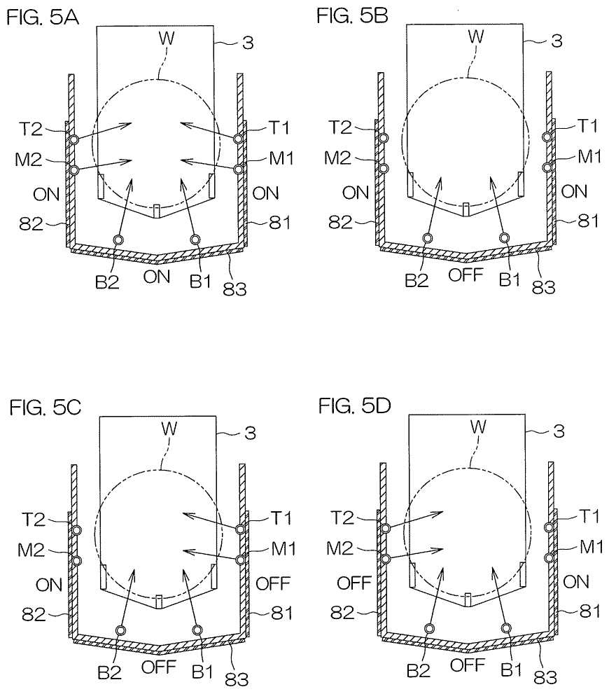

FIGS. 5A to 5D are views for illustrating an example of a relationship between discharge control of the processing liquid from the processing liquid nozzles 4 and control (heating control) of the heating device 8. The controller 10 individually controls opening and closing of open/close valves (ON/OFF valves) included in the flow rate adjusting unit 20, thereby to individually control discharge of the processing liquid from the plurality of processing liquid nozzles 4. It is noted that, FIGS. 5A to 5D do not illustrate control of the end wall heater 84. For example, in all the states of FIGS. 5A to 5D, the controller 10 energizes the end wall heater 84 and executes the heating by the end wall heater 84.

In the control state of FIG. 5A, all of the processing liquid nozzles 4 enter a discharge state in which the processing liquid is discharged, and all of the first side wall heater 81, the second side wall heater 82, and the bottom wall heater 83 enter an energized state (ON). Hence, the processing liquid is discharged inward from all of the first side wall 61, the second side wall 62, and the bottom wall 53 while all of the first side wall 61, the second side wall 62, and the bottom wall 53 are heated.

In the control state of FIG. 5B, the first bottom wall nozzle B1 and the second bottom wall nozzle B2 (hereinafter collectively referred to as the “bottom wall nozzles B1 and B2”) enter the discharge state, the first side wall upper nozzle T1 and the first side wall lower nozzle M1 (hereinafter collectively referred to as the “first side wall nozzles T1 and M1”) enter a discharge stop state, and the second side wall upper nozzle T2 and the second side wall lower nozzle M2 (hereinafter collectively referred to as the “second side wall nozzles T2 and M2”) also enter the discharge stop state. Regarding the heating device 8, the bottom wall heater 83 enters a deenergized state (OFF), the first side wall heater 81 enters the energized state (ON), and the second side wall heater 82 also enters the energized state (ON). Hence, the controller 10 performs bottom wall discharge control of discharging the processing liquid from the bottom wall nozzles B1 and B2 and stopping the output of the bottom wall heater 83, while stopping the discharge of the processing liquid from the first side wall nozzles T1 and M1 and the second side wall nozzles T2 and M2, and causes the first side wall heater 81 and the second side wall heater 82 to enter a heat generation state. In this manner, while the processing liquid is discharged inward from the bottom wall 53 while the heating of the bottom wall 53 is stopped, the first side wall 61 and the second side wall 62 from which the processing liquid is not discharged are heated by the side wall heaters 81 and 82.

In the control state of FIG. 5C, the bottom wall nozzles B1 and B2 enter the discharge state, the first side wall nozzles T1 and M1 enter the discharge state, and the second side wall nozzles T2 and M2 enter the discharge stop state. Regarding the heating device 8, the bottom wall heater 83 enters the deenergized state (OFF), the first side wall heater 81 enters the deenergized state (OFF), and the second side wall heater 82 enters the energized state (ON). Hence, the controller 10 performs the bottom wall discharge control of discharging the processing liquid from the bottom wall nozzles B1 and B2 and stopping the output of the bottom wall heater 83, and performs first side wall discharge control of discharging the processing liquid from the first side wall nozzles T1 and M1 and stopping the output of the first side wall heater 81. The controller 10 stops the discharge of the processing liquid from the second side wall nozzles T2 and M2, and causes the second side wall heater 82 to enter the heat generation state. In this manner, the processing liquid is discharged inward from the bottom wall 53 while the heating of the bottom wall 53 is stopped, and the processing liquid is discharged inward from the first side wall 61 while the heating of the first side wall 61 is stopped. The second side wall 62 to which the processing liquid is not discharged, on the other hand, is heated by the second side wall heater 82.

In the control state of FIG. 5D, the bottom wall nozzles B1 and B2 enter the discharge state, the first side wall nozzles T1 and M1 enter the discharge stop state, and the second side wall nozzles T2 and M2 enter the discharge state. Regarding the heating device 8, the bottom wall heater 83 enters the deenergized state (OFF), the first side wall heater 81 enters the energized state (ON), and the second side wall heater 82 enters the deenergized state (OFF). Hence, the controller 10 performs the bottom wall discharge control of discharging the processing liquid from the bottom wall nozzles B1 and B2 and stopping the output of the bottom wall heater 83, and performs second side wall discharge control of discharging the processing liquid from the second side wall nozzles T2 and M2 and stopping the output of the second side wall heater 82. The controller 10 stops the discharge of the processing liquid from the first side wall nozzles T1 and M1, and causes the first side wall heater 81 to enter the heat generation state. In this manner, the processing liquid is discharged inward from the bottom wall 53 while the heating of the bottom wall 53 is stopped, and the processing liquid is discharged inward from the second side wall 62 while the heating of the second side wall 62 is stopped. The first side wall 61 to which the processing liquid is not discharged, on the other hand, is heated by the first side wall heater 81.

In the control states of FIGS. 5B to 5D, heater heating is stopped for a wall in which the processing liquid nozzles 4 in a processing liquid discharge state are disposed, and heater heating is executed for a wall in which the processing liquid nozzles 4 in a processing liquid discharge stop state are disposed. Since the processing liquid is supplied in a state of being heated by the in-line heater 16 (typically in a state of a high temperature higher than room temperature), a discharge region of the processing liquid nozzle 4 in the processing liquid discharge state is heated by the amount of heat of the discharged processing liquid. In this respect, the heater heating is stopped for the wall in which the processing liquid nozzles 4 in the processing liquid discharge state are disposed. Since a high temperature processing liquid is not supplied to the vicinity of the processing liquid nozzles 4 in the processing liquid discharge stop state, the amount of heat from the supplied processing liquid is not supplied. In this respect, the heater heating is performed on the wall in the vicinity of the processing liquid nozzles 4 in the processing liquid discharge stop state. In this manner, a temperature distribution in the processing liquid stored in the processing tank 2, more specifically, a temperature distribution in a plane intersecting the arrangement direction R1 is made even. Consequently, since the processing liquid having an even temperature comes into contact with the principal surface of each substrate W, in-plane evenness of the substrate processing can be improved.

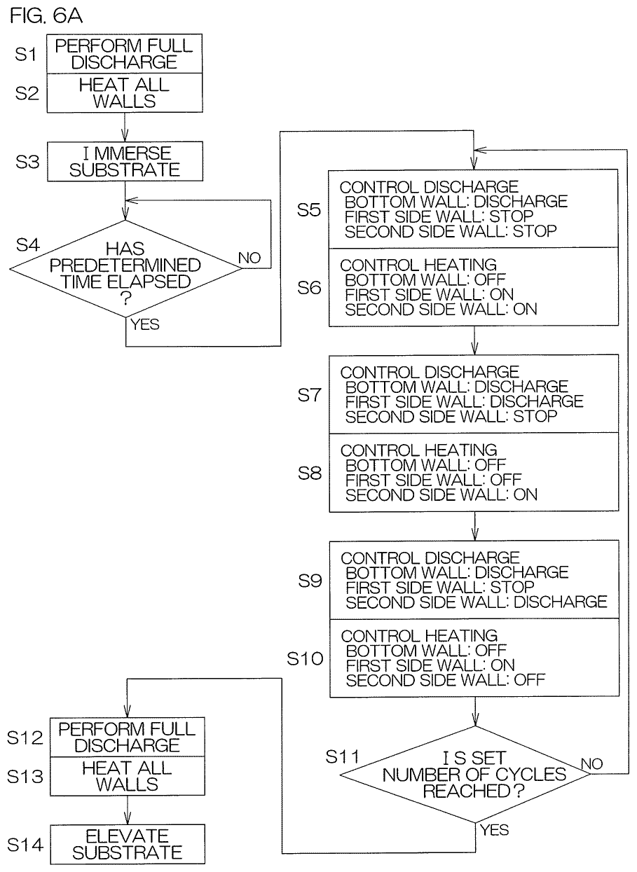

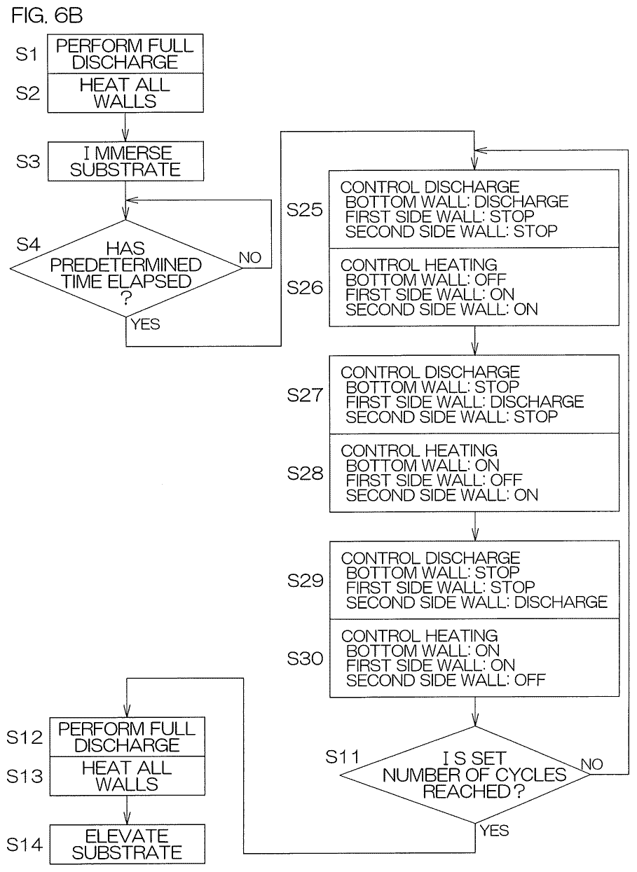

FIG. 6A is a flowchart for illustrating an example of the processing, and illustrates a control processing example performed by the controller 10. Before the substrates W which are processing targets are immersed, the controller 10 controls all of the processing liquid nozzles 4 to enter the discharge state and all of the heaters 84, 81, 82, and 83 to enter the energized state (Steps S1 and S2). From this state, the controller 10 controls the lifter driving mechanism 6 to lower the lifter 3 to the processing position. Consequently, the plurality of substrates W held by the lifter 3 are immersed in the processing liquid (Step S3). When the substrate W enters an immersion state, the controller 10 stands by for elapsing of a predetermined time (for example, 5 minutes) taken to stabilize the temperature of the processing liquid in the processing tank 2 (Step S4). During this time, the control state illustrated in FIG. 5A (full discharge/full heating state) is achieved, that is, all of the processing liquid nozzles 4 enter the processing liquid discharge state, and all of the heaters 84, 81, 82, and 83 are controlled to enter the energized state (ON).

When the predetermined time elapses (Step S4: YES), the controller 10 cyclically switches between a first control state (steps S5 and S6), a second control state (steps S7 and S8), and a third control state (steps S9 and S10) to be described below. It is noted that, in any of the control states, the end wall heater 84 is controlled to enter the energized state (ON).

The first control state indicates a bottom wall discharge/side wall heating state illustrated in FIG. 5B. The bottom wall nozzles B1 and B2 are controlled to enter the discharge state, and the first side wall nozzles T1 and M1 and the second side wall nozzles T2 and M2 are controlled to enter the discharge stop state (Step S5). The bottom wall heater 83 is controlled to enter the deenergized state (OFF), and the first side wall heater 81 and the second side wall heater 82 are controlled to enter the energized state (ON) (Step S6).

The second control state indicates a bottom wall⋅first side wall discharge/second side wall heating state illustrated in FIG. 5C. The bottom wall nozzles B1 and B2 are controlled to enter the discharge state, the first side wall nozzles T1 and M1 are controlled to enter the discharge state, and the second side wall nozzles T2 and M2 are controlled to enter the discharge stop state (Step S7). The bottom wall heater 83 is controlled to enter the deenergized state (OFF), the first side wall heater 81 is controlled to enter the deenergized state (OFF), and the second side wall heater 82 is controlled to enter the energized state (ON) (Step S8).

The third control state indicates a bottom wall⋅second side wall discharge/first side wall heating state illustrated in FIG. 5D. The bottom wall nozzles B1 and B2 are controlled to enter the discharge state, the first side wall nozzles T1 and M1 are controlled to enter the discharge stop state, and the second side wall nozzles T2 and M2 are controlled to enter the discharge state (Step S9). The bottom wall heater 83 is controlled to enter the deenergized state (OFF), the first side wall heater 81 is controlled to enter the energized state (ON), and the second side wall heater 82 is controlled to enter the deenergized state (OFF) (Step S10).

The first control state, the second control state, and the third control state may be sequentially and cyclically executed in at least one cycle (for example, six cycles) by taking a predetermined time (for example, two minutes) for each state (Step S11). An execution order of the three control states is arbitrary.

It is noted that, the first control state may be omitted, and the second control state and the third control state may be alternately executed. That is, the discharge of the processing liquid from the bottom wall nozzles B1 and B2 may not be stopped.

After such cyclic switching control of discharge/heating state is executed in a preset number of cycles (Step S11: YES), the controller 10 again controls a full discharge/full heating state illustrated in FIG. 5A (steps S12 and S13) and maintains the state for a predetermined time (for example, 3 minutes).

Thereafter, the controller 10 controls the lifter driving mechanism 6 to lift the lifter 3, and elevates the substrates W held by the lifter 3 above the processing liquid (Step S14).

FIG. 6B is a flowchart for illustrating another example of the processing, and illustrates a control processing example performed by the controller 10. Before the substrates W which are processing targets are immersed, the controller 10 controls all of the processing liquid nozzles 4 to enter the discharge state and all of the heaters 84, 81, 82, and 83 to enter the energized state (Steps S1 and S2). From this state, the controller 10 controls the lifter driving mechanism 6 to lower the lifter 3 to the processing position. Consequently, the plurality of substrates W held by the lifter 3 are immersed in the processing liquid (Step S3). When the substrate W enters an immersion state, the controller 10 stands by for elapsing of a predetermined time (for example, 5 minutes) taken to stabilize the temperature of the processing liquid in the processing tank 2 (Step S4). During this time, the control state illustrated in FIG. 5A (full discharge/full heating state) is achieved, that is, all of the processing liquid nozzles 4 enter the processing liquid discharge state, and all of the heaters 84, 81, 82, and 83 are controlled to enter the energized state (ON).

When the predetermined time has elapsed (Step S4: YES), the controller 10 cyclically switches between a first control state (steps S25 and S26), a second control state (steps S27 and S28), and a third control state (steps S29 and S30) to be described below. It is noted that, in any control states, the end wall heater 84 is controlled to enter the energized state (ON).

The first control state indicates that the bottom wall nozzles B1 and B2 are controlled to enter the discharge state, and the first side wall nozzles T1 and M1 and the second side wall nozzles T2 and M2 are controlled to enter the discharge stop state (Step S25). The bottom wall heater 83 is controlled to enter the deenergized state (OFF), and the first side wall heater 81 and the second side wall heater 82 are controlled to enter the energized state (ON) (Step S26).

The second control state indicates that the bottom wall nozzles B1 and B2 are controlled to enter the discharge stop state, the first side wall nozzles T1 and M1 are controlled to enter the discharge state, and the second side wall nozzles T2 and M2 are controlled to enter the discharge stop state (Step S27). The bottom wall heater 83 is controlled to enter the energized state (ON), the first side wall heater 81 is controlled to enter the deenergized state (OFF), and the second side wall heater 82 is controlled to enter the energized state (ON) (Step S28).

The third control state indicates that the bottom wall nozzles B1 and B2 are controlled to enter the discharge stop state, the first side wall nozzles T1 and M1 are controlled to enter the discharge stop state, and the second side wall nozzles T2 and M2 are controlled to enter the discharge state (Step S29). The bottom wall heater 83 is controlled to enter the energized state (ON), the first side wall heater 81 is controlled to enter the energized state (ON), and the second side wall heater 82 is controlled to enter the deenergized state (OFF) (Step S30).

The first control state, the second control state, and the third control state may be sequentially and cyclically executed in at least one cycle (for example, six cycles) by taking a predetermined time (for example, two minutes) for each state. An execution order of the three control states is arbitrary.

After such cyclic switching control of a discharge/heating state is executed in a preset number of cycles (Step S11: YES), the controller 10 again controls a full discharge/full heating state illustrated in FIG. 5A (steps S12 and S13) and maintains the state for a predetermined time (for example, 3 minutes).

Thereafter, the controller 10 controls the lifter driving mechanism 6 to lift the lifter 3, and elevates the substrates W held by the lifter 3 above the processing liquid (Step S14).

As described above, the substrate processing apparatus 1 of this preferred embodiment includes the plurality of processing liquid nozzles 4 to discharge the processing liquid into the internal space of the processing tank 2 from a plurality of different positions in the processing tank 2, and the heating device 8 including the plurality of heaters 84, 81, 82, and 83 to respectively heat a plurality of different regions of the wall of the processing tank 2. The controller 10 individually controls discharge of the processing liquid from the plurality of processing liquid nozzles 4 and individually controls outputs of the plurality of heaters 84, 81, 82 and 83. Consequently, the processing liquid in the processing tank 2 can be evenly applied to the portions of the principal surfaces of the substrates W, and accordingly, the evenness of the processing in the principal surfaces of the substrates W can be improved.

Also, in this preferred embodiment, the controller 10 individually controls the outputs of the plurality of heaters 81, 82 and 83 according to the discharge state of the processing liquid from the plurality of processing liquid nozzles 4. Consequently, since an appropriate heating state can be realized depending on the discharge state of the processing liquid, the processing liquid in the processing tank 2 can be evenly applied to each portion of the principal surface of the substrate W, and accordingly, the evenness of the processing in the principal surface of the substrate W can be improved.

Also, the controller 10 individually controls the outputs of the plurality of heaters 81, 82 and 83 so that the processing liquid in the discharge region of a processing liquid nozzle 4 from which discharge of the processing liquid is stopped is heated, among the plurality of processing liquid nozzles 4. Consequently, since the processing liquid in the discharge region of the processing liquid nozzle 4 from which the discharge is stopped can be heated, the temperature of the processing liquid can be locally adjusted by the heaters 81, 82 and 83 in a region where it is difficult to perform the temperature adjustment by supplying the processing liquid. Consequently, since temperature unevenness of the processing liquid in the processing tank 2 can be prevented, the evenness of the processing in the principal surfaces of the substrates W can be improved. The discharge region of the processing liquid nozzle 4 refers to a region in the vicinity of the discharge port 41 of the processing liquid nozzle 4.

Also, the controller 10 individually controls the discharge/stop of the processing liquid through the plurality of processing liquid nozzles 4, and individually controls the outputs of the plurality of heaters 81, 82 and 83 so that a heat generation amount of a heater closest to the processing liquid nozzle 4 through which the processing liquid is discharged is small (specifically heat generation is stopped), and a heat generation amount of a heater closest to the processing liquid nozzle 4 through which no processing liquid is discharged is large (specifically the heat generation state is started). Consequently, local heating by the heaters 81, 82 and 83 can be appropriately controlled depending on a degree of temperature adjustment by the supply of the processing liquid, and as a result, temperature unevenness in the processing tank 2 can be prevented. This enables the evenness of the processing in the principal surfaces of the substrates W to be improved.

In this preferred embodiment, the plurality of heaters include the first side wall heater 81 to heat the first side wall 61 of the processing tank 2, the second side wall heater 82 to heat the second side wall 62 of the processing tank 2, and the bottom wall heater 83 to heat the bottom wall 53 of the processing tank 2. Also, the plurality of processing liquid nozzles 4 include the first side wall nozzles T1 and M1 to discharge the processing liquid from the first side wall 61 toward an inside of the internal space of the processing tank 2, the second side wall nozzles T2 and M2 to discharge the processing liquid from the second side wall 62 toward the inside of the internal space of the processing tank 2, and the bottom wall nozzles B1 and B2 to discharge the processing liquid from the bottom wall 53 toward the inside of the internal space of the processing tank 2. Then, the controller 10 can execute the first side wall discharge control of discharging the processing liquid from the first side wall nozzles T1 and M1 and stopping the output of the first side wall heater 81. Also, the controller 10 can execute the second side wall discharge control of discharging the processing liquid from the second side wall nozzles T2 and M2 and stopping the output of the second side wall heater 82. Also, the controller 10 can execute bottom wall discharge control of discharging the processing liquid from the bottom wall nozzles B1 and B2 and stopping the output of the bottom wall heater 83.

In the first side wall discharge control, since, in the vicinity of the first side wall nozzles T1 and M1, the temperature adjustment is performed by the processing liquid discharged from the first side wall nozzles T1 and M1, the output of the first side wall heater 81 is stopped. Also, in the second side wall discharge control, since, in the vicinity of the second side wall nozzles T2 and M2, the temperature adjustment is performed by the processing liquid discharged from the second side wall nozzles T2 and M2, the output of the second side wall heater 82 is stopped. Similarly, in the bottom wall discharge control, since, in the vicinity of the bottom wall nozzles B1 and B2, the temperature adjustment is performed by the processing liquid discharged from the bottom wall nozzles B1 and B2, the output of the bottom wall heater 83 is stopped. In this manner, the outputs of the heaters can be appropriately controlled depending on the discharge of the processing liquid, whereby the evenness of the processing in the principal surfaces of the substrates W can be improved.

In the state of FIG. 5C, the controller 10 stops discharge of the processing liquid from the second side wall nozzles T2 and M2 and causes the second side wall heater 82 to enter a heat generation state when simultaneously executing the first side wall discharge control and the bottom wall discharge control. Hence, regions in the vicinity of the second side wall nozzles T2 and M2 through which no processing liquid is discharged is heated by the second side wall heater 82. Consequently, since temperature unevenness of the processing liquid in the processing tank 2 can be prevented, the evenness of the processing in the principal surfaces of the substrates W can be improved.

Also, in the state of FIG. 5B, the controller 10 stops discharge of the processing liquid from the first side wall nozzles T1 and M1 and the second side wall nozzles T2 and M2 and causes the first side wall heater 81 and the second side wall heater 82 to enter the heat generation state while executing the bottom wall discharge control. Hence, regions in the vicinity of the first side wall nozzles T1 and M2 and the second side wall nozzles T2 and M2 through which no processing liquid is discharged are heated by the first side wall heater 81 and the second side wall heater 82, respectively. Consequently, since temperature unevenness of the processing liquid in the processing tank 2 can be prevented, the evenness of the processing in the principal surfaces of the substrates W can be improved.

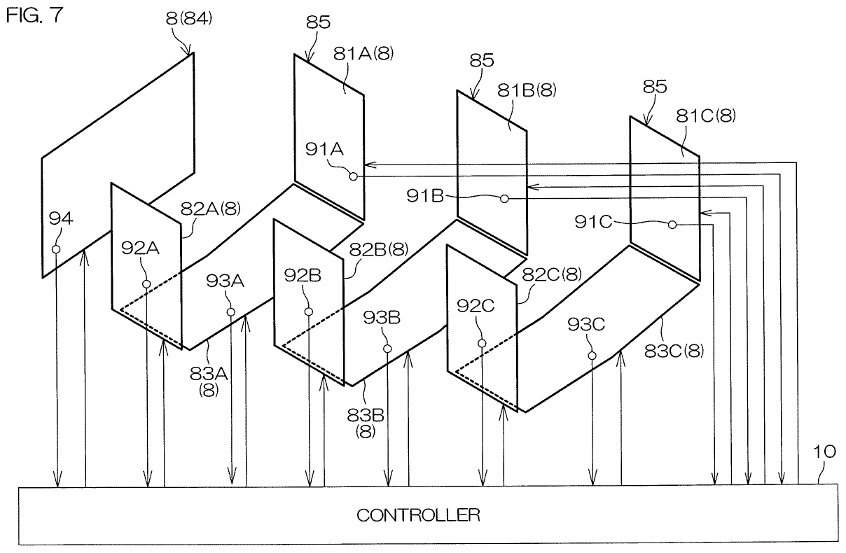

FIG. 7 is a diagram for illustrating a second preferred embodiment of the present invention. In this preferred embodiment, a configuration of the heating device 8 is different from that of the preferred embodiment described above. Specifically, the first side wall heater 81 disposed on the outer surface of the first side wall 61 includes a plurality of first side wall zone heaters 81A, 81B, and 81C. The plurality of first side wall zone heaters 81A, 81B, and 81C heat the first side wall 61 in a plurality of respective regions divided in the arrangement direction R1, thereby heating the processing liquid which is in contact with the inner surface of the first side wall 61. Similarly, the second side wall heater 82 disposed on the outer surface of the second side wall 62 includes a plurality of second side wall zone heaters 82A, 82B, and 82C. The plurality of second side wall zone heaters 82A, 82B, and 82C heat the second side wall 62 in a plurality of respective regions divided in the arrangement direction R1, thereby heating the processing liquid which is in contact with the inner surface of the second side wall 62. Further similarly, the bottom wall heater 83 disposed on the outer surface (lower surface) of the bottom wall 53 of the processing tank 2 includes a plurality of bottom wall zone heaters 83A, 83B, and 83C. The plurality of bottom wall zone heaters 83A, 83B, and 83C heat the bottom wall 53 in a plurality of respective regions divided in the arrangement direction R1, thereby heating the processing liquid which is in contact with the inner surface (upper surface) of the bottom wall 53.

In this preferred embodiment, disposition regions of the plurality of first side wall zone heaters 81A, 81B, and 81C, the plurality of second side wall zone heaters 82A, 82B, and 82C, and the plurality of bottom wall zone heaters 83A, 83B, and 83C are divided at the same positions in the arrangement direction R1. The first side wall zone heaters 81A, 81B, and 81C, the second side wall zone heaters 82A, 82B, and 82C, and the bottom wall zone heaters 83A, 83B, and 83C at the same positions in the arrangement direction R1 form a plurality of band-shaped zone heaters 85A, 85B, and 85C, respectively. Hence, the plurality of zone heaters 85A, 85B, and 85C that heat the pair of side walls 61 and 62 and the bottom wall 53 are provided in the plurality of respective regions divided in the arrangement direction R1. In this preferred embodiment, the plurality of (three in the illustrated example) zone heaters 85A, 85B, and 85C are disposed in a plurality of regions (three regions in the illustrated example) equally divided in the arrangement direction R1. Hence, widths of the plurality of zone heaters 85A, 85B, and 85C in the arrangement direction R1 are substantially equal.

Temperature sensors 94, 91A, 91B, 91C, 92A, 92B, 92C, 93A, 93B, and 93C (typically thermocouples) are disposed on the end wall heater 84, the first side wall zone heaters 81A, 81B, and 81C, the second side wall zone heaters 82A, 82B, and 82C, and the bottom wall zone heaters 83A, 83B, and 83C. The temperature sensors 94, 91A, 91B, 91C, 92A, 92B, 92C, 93A, 93B, and 93C detect the temperatures of the end wall heater 84, the first side wall zone heaters 81A, 81B, and 81C, the second side wall zone heaters 82A, 82B, and 82C, and the bottom wall zone heaters 83A, 83B, and 83C, respectively. Consequently, the temperature sensor 94 indirectly detects a temperature of the first end wall 51 with which the end wall heater 84 is in contact. Similarly, the temperature sensors 91A, 91B, and 91C indirectly detect the temperature of the first side wall 61 at a position with which the temperature sensors are in contact, the temperature sensors 92A, 92B, and 92C indirectly detect the temperature of the second side wall 62 at positions with which the temperature sensors are in contact, and the temperature sensors 93A, 93B, and 93C indirectly detect a temperature of the bottom wall 53 at positions where the temperature sensors are in contact.

Energization of the end wall heater 84, the first side wall zone heaters 81A, 81B, and 81C, the second side wall zone heaters 82A, 82B, and 82C, and the bottom wall zone heaters 83A, 83B, and 83C is controlled by the controller 10. The temperature sensors 94, 91A, 91B, 91C, 92A, 92B, 92C, 93A, 93B, and 93C are connected to the controller 10. The controller 10 controls outputs (supply power) of the end wall heater 84, the first side wall zone heaters 81A, 81B, and 81C, the second side wall zone heaters 82A, 82B, and 82C, and the bottom wall zone heaters 83A, 83B, and 83C based on a predetermined set temperature and detected temperatures detected by the temperature sensors 94, 91A, 91B, 91C, 92A, 92B, 92C, 93A, 93B, and 93C.

The set temperatures for the end wall heater 84, the first side wall zone heaters 81A, 81B, and 81C, the second side wall zone heaters 82A, 82B, and 82C, and the bottom wall zone heaters 83A, 83B, and 83C may be equal to or different from each other. Typically, the set temperatures for the end wall heater 84, the first side wall zone heaters 81A, 81B, and 81C, the second side wall zone heaters 82A, 82B, and 82C, and the bottom wall zone heaters 83A, 83B, and 83C are preferably determined to make a distribution of the temperature of the processing liquid in the processing tank 2 even in the arrangement direction R1 (to have a minimum variation) based on experiments or simulations performed in advance.

In order to make the temperature of the processing liquid in the processing tank 2 uniform in the arrangement direction R1, the controller 10 controls the plurality of zone heaters 85A, 85B, and 85C so that a heat generation amount (specifically a heat generation amount per unit length in the arrangement direction R1) of the zone heater 85C (the second zone heater, that is, the first side wall zone heater 81C, the second side wall zone heater 82C, and the bottom wall zone heater 83C) closest to the second end wall 52 is larger than that of the zone heater 85A (the first zone heater, that is, the first side wall zone heater 81A, the second side wall zone heater 82A, and the bottom wall zone heater 83A) closest to the first end wall 51.

This is because, the zone heater 85C close to the second end wall 52 has to supply a larger amount of heat to the processing liquid than the zone heater 85A close to the first end wall 51 does, since no heater is disposed on the second end wall 52, while the first end wall 51 is heated by the end wall heater 84. For example, a set temperature of the zone heater 85A (the first zone heater) closest to the first end wall 51 may be set to a first temperature, and a set temperature of the zone heater 85C (the second zone heater) closest to the second end wall 52 may be set to a second temperature higher than the first temperature. Appropriate setting of the first temperature and the second temperature enables temperatures of the processing liquid in regions close to the first end wall 51 and the second end wall 52 in the processing tank 2, respectively, to be made substantially equal.

As described above, according to this preferred embodiment, the immersion of the plurality of substrates W held by the lifter 3 in the processing liquid stored in the processing tank 2 enables the plurality of substrates W to be collectively processed with the processing liquid. In a state in which the plurality of substrates W are immersed in the processing liquid, the back plate 31 (back portion) of the lifter 3 is interposed between the plurality of substrates W and the first end wall 51. In the processing tank 2, the heating device 8 (the end wall heater 84 and the zone heaters 85A, 85B, and 85C) that heats the processing liquid stored in the processing tank by heating the walls constituting the processing tank 2 is provided. Specifically, the end wall heater 84 that heats the first end wall 51 which is one of the end walls facing each other in the arrangement direction R1 is provided. Also, the plurality of zone heaters 85A, 85B, and 85C that heat at least one of the pair of side walls 61 and 62 and the bottom wall 53 are provided.

The end wall heater 84 that heats the first end wall 51 is provided, while no heater is provided on the second end wall 52. Therefore, the processing liquid stored in the processing tank 2 may have a temperature distribution having a gradient in the arrangement direction R1. In this respect, the zone heaters 85A, 85B, and 85C heat at least one of the pair of side walls 61 and 62 and the bottom wall 53 in the plurality of respective regions divided in the arrangement direction R1, and the zone heaters are individually controlled by the controller 10 (heater controlling portion). Consequently, since the heating of the plurality of regions divided in the arrangement direction R1 can be individually controlled, the processing liquid in the processing tank 2 can be appropriately heated in each of the region close to the first end wall 51 and the region close to the second end wall 52. Specifically, an even temperature distribution having a small gradient in the arrangement direction R1 can be made. This enables the evenness of the processing performed on the plurality of substrates W to be improved.

More specifically, in this preferred embodiment, the controller 10 controls the outputs of the plurality of zone heaters 85A, 85B, and 85C so that the zone heater 85C (the second zone heater) closest to the second end wall 52 has a heat generation amount larger than that of the zone heater 85A (the first zone heater) closest to the first end wall 51. Consequently, a larger amount of heat can be supplied to the processing liquid in the processing tank 2 in the region close to the second end wall 52 on which no heater is disposed than in the region close to the first end wall 51 on which the end wall heater 84 is disposed. Hence, the temperature distribution of the processing liquid in the arrangement direction R1 can become even.

In this preferred embodiment, the zone heaters 85A, 85B, and 85C are disposed respectively in three regions divided in the arrangement direction R1 and are individually controlled. Hence, in a region in the vicinity of the first end wall 51 which is heated by the end wall heater 84 and is positioned with the back plate 31 of the lifter 3 interposed between the substrate W and the first end wall, a region in the vicinity of the second end wall 52 on which no heater is disposed, and an intermediate region between the regions, the walls constituting the processing tank 2 can be appropriately and individually heated. Consequently, the temperature distribution in the arrangement direction R1 can become even. It is obvious that two or four or more regions divided in the arrangement direction R1 may be provided. As the number of divisions increases, an even temperature distribution can be easily achieved. However, the configuration and control details of the controller 10 become complicated, and the number of wiring steps increases. Therefore, it is preferable to select a necessary and sufficient number of divisions.

Also, in this preferred embodiment, the controller 10 further individually controls the end wall heater 84. Consequently, the temperature distribution of the processing liquid in the arrangement direction R1 can be made more even.

In this preferred embodiment, the outer tank 7 to receive the processing liquid overflowing from the processing tank 2 is provided. Consequently, the overflowing of the processing liquid from the processing tank 2 to the outer tank 7 enables the processing to be performed on the plurality of substrates W while the processing liquid is supplied to the processing tank 2 such that the processing liquid is circulated in the tank, and switching between the substrates is performed. The storage space 70 of the outer tank 7 faces an outer surface of the second end wall 52 and has the second end portion space 72 having a depth equal to or larger than the depth of the internal space of the processing tank 2. That is, the depth of the second end portion space 72 is substantially equal to or larger than the depth of the internal space of the processing tank 2. In this preferred embodiment, the second end portion space 72 overlaps the entire second end wall 52 when viewed in the arrangement direction R1. The deep second end portion space 72 provided as described above is advantageous in that a circulation flow rate can be increased, in a case where the processing liquid is pumped out from the outer tank 7 and circulated to the processing tank 2 through the circulation piping 13. Specifically, when the circulation flow rate is increased using the high-capacity pump 15, it is possible to prevent the entrance end 13a of the circulation piping 13 from being exposed in the air and entering a liquid shortage state if the entrance end 13a of the circulation piping 13 is disposed at the bottom portion of the deep second end portion space 72.

Since the second end portion space 72 facing the second end wall 52 is provided, the heater cannot be disposed on the outer surface of the second end wall 52. Therefore, the temperature distribution of the processing liquid in the processing tank 2 may have a gradient in the arrangement direction R1. In this respect, in this preferred embodiment, the plurality of zone heaters 85A, 85B, and 85C are disposed in the plurality of regions divided in the arrangement direction R1, and the plurality of zone heaters 85A, 85B, and 85C are individually controlled. Consequently, it is possible to suppress the temperature gradient in the arrangement direction R1 and to realize an even temperature distribution of the processing liquid in the processing tank 2.

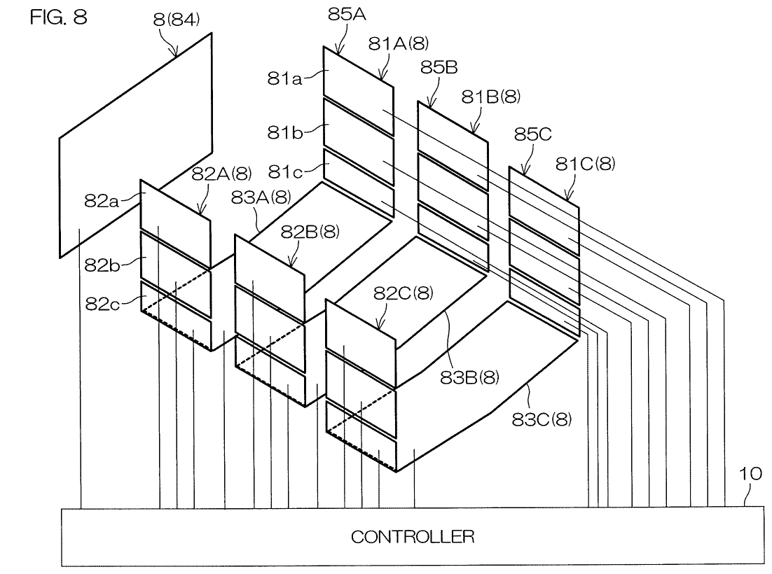

FIG. 8 is a diagram for illustrating a third preferred embodiment of the present invention, and illustrates a modification example of the zone heaters 85A, 85B, and 85C. In this preferred embodiment, each of the first side wall zone heaters 81A, 81B, and 81C has a plurality of heater portions 81a, 81b, and 81c divided in the up-down direction. Similarly, each of the second side wall zone heaters 82A, 82B, and 82C has a plurality of heater portions 82a, 82b, and 82c divided in the up-down direction. The controller 10 individually controls a plurality of heater portions 81a, 81b, and 81c, and 82a, 82b, and 82c. Consequently, the temperature distribution in the processing liquid can be made even not only in the arrangement direction R1 but also in the up-down direction. Consequently, not only the evenness of the processing performed on the plurality of substrates W, but also the evenness of the processing in the principal surface of each substrate W can be made uniform.

It is noted that, in the example illustrated in FIG. 8, the number of divisions in the up-down direction is three, but the number of divisions may be two or four or more.

Also, in the example illustrated in FIG. 8, all of the first side wall zone heaters 81A, 81B, and 81C and all of the second side wall zone heaters 82A, 82B, and 82C are divided in the up-down direction; however, only some side wall zone heaters (for example, the first side wall zone heater 81B and the second side wall zone heater 82B in a central region in the arrangement direction R1) may be divided in the up-down direction.

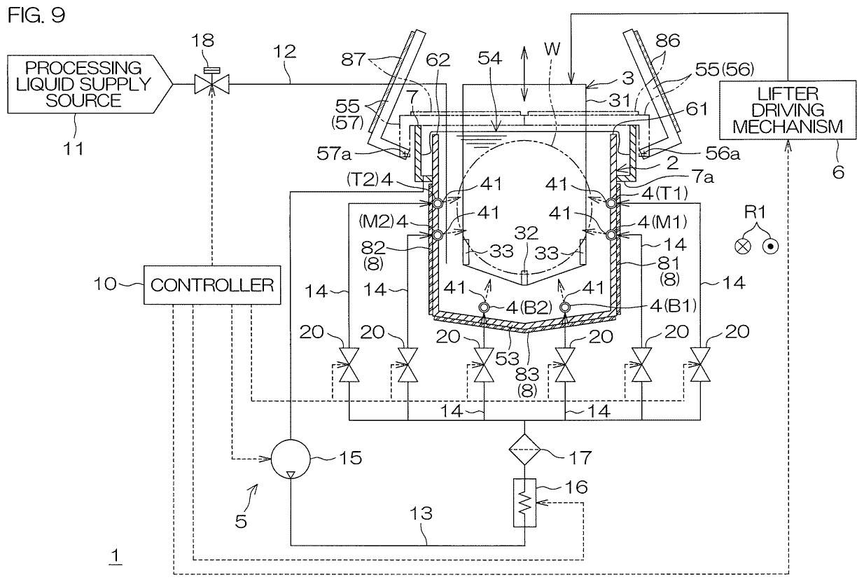

FIG. 9 is a diagram for illustrating a fourth preferred embodiment of the present invention. In this preferred embodiment, a first lid heater 86 and a second lid heater 87 are disposed on the first lid member 56 and the second lid member 57, respectively. Energization of the first lid heater 86 and the second lid heater 87 is individually controlled by controller 10 independently of the end wall heater 84, the first side wall heater 81, the second side wall heater 82, and the bottom wall heater 83. Since the processing liquid in the processing tank 2 can be heated from above by the first lid heater 86 and the second lid heater 87, the temperature distribution in the processing liquid can be made still more even. In particular, since the heater is not disposed in the outer tank 7, a temperature of an upper region in the processing tank 2 is likely to be decreased. Hence, the heating from above by the first lid heater 86 and the second lid heater 87 effectively contributes to evenness of the temperature distribution. As described above, the heating of the lid 55 of the processing tank 2 enables the processing liquid to be heated also from above. Consequently, the processing liquid can be prevented from being cooled, and the temperature distribution of the processing liquid can be made still more even.

Features of this preferred embodiment can also be combined with the above-described second and third preferred embodiments.

Although the preferred embodiments of the present invention have been described above, the present invention can be implemented in yet other preferred embodiments.

For example, in the above-described preferred embodiments, the example in which ON/OFF control of the heater is performed has been described, but a configuration may be employed in which the heat generation amount of the heater is controlled stepwise or continuously by changing power supplied to the heater stepwise or continuously.

Also, the number and arrangement of the processing liquid nozzles 4 in the above-described preferred embodiments are provided as examples. Also, a main discharge direction of the processing liquid from the processing liquid nozzles 4 may not necessarily be toward the substrate W. For example, an upward flow (upflow) of the processing liquid from the bottom wall 53 may be formed in the processing tank 2 by directing a main discharge direction of the bottom wall nozzles B1 and B2 toward the central portion of the bottom wall 53 along a direction parallel to the principal surface of the substrate W.

Although the preferred embodiment of the present invention has been described in detail, these are merely specific examples used to clarify the technical contents of the present invention, and the present invention should not be construed as limited to these specific examples, and the scope of the present invention is limited only by the accompanying claims.

What is claimed is:

1. A substrate processing apparatus comprising:
a processing tank including a wall defining an internal space to store a processing liquid;
a lifter, having a holding portion to hold a substrate, to immerse the substrate held by the holding portion in the processing liquid stored in the internal space;
a plurality of processing liquid nozzles to discharge the processing liquid into the internal space from a plurality of respective different positions in the processing tank;
a heating device including a plurality of heaters to respectively heat a plurality of different regions of the wall; and
a controller configured or programmed to individually control discharge of the processing liquid from the plurality of processing liquid nozzles and individually control outputs of the plurality of heaters.

2. The substrate processing apparatus according to claim 1, wherein the controller is configured or programmed to individually control the outputs of the plurality of heaters depending on a discharge state of the processing liquid from the plurality of processing liquid nozzles.

3. The substrate processing apparatus according to claim 1, wherein the controller is configured or programmed to individually control the outputs of the plurality of heaters so as to heat a processing liquid in a discharge region of a processing liquid nozzle through which discharge of the processing liquid is stopped, among the plurality of processing liquid nozzles.

4. The substrate processing apparatus according to claim 1, wherein the controller is configured or programmed to individually control discharge/stop of the processing liquid through the plurality of processing liquid nozzles, and individually control the outputs of the plurality of heaters so that a heat generation amount of a heater closest to the processing liquid nozzle through which the processing liquid is discharged is small and a heat generation amount of a heater closest to the processing liquid nozzle through which no processing liquid is discharged is large.

5. The substrate processing apparatus according to claim 1, wherein
the wall includes a first side wall and a second side wall facing each other, and a bottom wall,
the plurality of heaters include a first side wall heater to heat the first side wall, a second side wall heater to heat the second side wall, and a bottom wall heater to heat the bottom wall,
the plurality of processing liquid nozzles include a first side wall nozzle to discharge a processing liquid from the first side wall toward an inside of the internal space, a second side wall nozzle to discharge a processing liquid from the second side wall toward the inside of the internal space, and a bottom wall nozzle to discharge a processing liquid from the bottom wall toward the inside of the internal space, and
the controller is configured or programmed to execute at least one of
first side wall discharge control to discharge a processing liquid from the first side wall nozzle and to stop an output of the first side wall heater,
second side wall discharge control to discharge a processing liquid from the second side wall nozzle and to stop an output of the second side wall heater, and
bottom wall discharge control to discharge a processing liquid from the bottom wall nozzle and to stop an output of the bottom wall heater.

6. The substrate processing apparatus according to claim 5, wherein the controller is configured or programmed to stop discharge of a processing liquid from the second side wall nozzle and to cause the second side wall heater to enter a heat generation state when simultaneously executing the first side wall discharge control and the bottom wall discharge control.

7. The substrate processing apparatus according to claim 5, wherein the controller is configured or programmed to stop discharge of processing liquids from the first side wall nozzle and the second side wall nozzle and to cause the first side wall heater and the second side wall heater to enter a heat generation state when performing the bottom wall discharge control.

8. The substrate processing apparatus according to claim 1, wherein
the wall includes a pair of end walls facing each other in an arrangement direction that is a predetermined horizontal direction, a pair of side walls which face each other in an intersecting direction that is a horizontal direction intersecting the arrangement direction and are coupled to the pair of end walls, and a bottom wall coupled to the pair of end walls and the pair of side walls,
the holding portion is to hold a plurality of substrates arranged in the arrangement direction in a standing posture,
the lifter includes a back portion connected to the holding portion, and is to immerse the plurality of substrates in the processing liquid in the processing tank in a state in which the back portion is interposed between the plurality of substrates and a first end wall which is one of the pair of end walls,
the plurality of heaters include an end wall heater disposed on the first end wall and a plurality of zone heaters disposed on at least one of the pair of side walls and the bottom wall in a plurality of respective regions divided in the arrangement direction, and the heating device does not include a heater disposed on a second end wall that is the other of the pair of end walls, and
the controller is configured or programmed to individually control outputs of the plurality of zone heaters.

9. The substrate processing apparatus according to claim 8, wherein
the plurality of zone heaters include a first zone heater disposed in a region closest to the first end wall among the plurality of regions and a second zone heater disposed in a region closest to the second end wall among the plurality of regions, and
the controller is configured or programmed to control the outputs of the plurality of zone heaters so that the second zone heater has a heat generation amount larger than that of the first zone heater.

10. The substrate processing apparatus according to claim 8, further comprising an outer tank having a storage space to receive a processing liquid overflowing from the processing tank, wherein
the storage space has an end portion space having a depth equal to or larger than a depth of the internal space of the processing tank in a region facing an outer surface of the second end wall.

11. The substrate processing apparatus according to claim 8, further comprising a lid to open and close an opening of the processing tank, wherein
the heating device further includes a lid heater disposed on the lid.

12. The substrate processing apparatus according to claim 8, wherein at least one of the plurality of zone heaters has a plurality of heater portions divided in an up-down direction, and the controller is configured or programmed to individually control the plurality of heater portions.

13. A substrate processing method comprising:
immersing a substrate in a processing liquid stored in a processing tank including a wall defining an internal space to store the processing liquid;
individually controlling discharge of a processing liquid from a plurality of different positions in the processing tank to the internal space by a controller; and
individually controlling, by the controller, a plurality of heaters to respectively heat a plurality of different regions of the wall.
